(19) United States
(12) Patent Application Publication
(10) Pub. No.: US 2014/0073136 A1
(43) Pub. Date: Mar. 13, 2014

(54) SEMICONDUCTOR DEVICE MANUFACTURING METHOD

(71) Applicant: KABUSHIKI KAISHA TOSHIBA, Tokyo (JP)

(72) Inventors: Gaku MINAMIHABA, Yokohma-shi (JP); Akifumi Gawase, Kuwana-shi (JP); Yukiteru Matsui, Nagoya-shi (JP)

(21) Appl. No.: 14/016,672

(22) Filed: Sep. 3, 2013

(30) Foreign Application Priority Data
Sep. 7, 2012 (JP) 2012-197886

(51) Int. Cl. H01L 21/306

(52) U.S. Cl. CPC H01L 21/30625
USPC 438/692

(57) ABSTRACT

According to one embodiment, a semiconductor device manufacturing method comprises forming an interlayer dielectric film on a semiconductor substrate, forming a film on the interlayer dielectric film to cover a recess and projection formed on a surface of the interlayer dielectric film, polishing the film by CMP to expose the interlayer dielectric film, and etching the film and the interlayer dielectric film such that etching rates of the film and the interlayer dielectric film are equal.

### CROSS-REFERENCE TO RELATED APPLICATIONS

This application is based upon and claims the benefit of priority from the prior Japanese Patent Application No. 2012-197886, filed Sep. 7, 2012, the entire contents of which are incorporated herein by reference.

### FIELD

Embodiments described herein relate generally to a semiconductor device manufacturing method.

### BACKGROUND

Projections and recesses are formed on a semiconductor substrate surface on which devices (elements) are formed. When interconnections are formed by forming an interlayer dielectric film such as a silicon oxide film on these projections and recesses, projections and recesses are also formed on the interlayer dielectric film and may shortcircuit the interconnections. Therefore, the silicon oxide film must be planarized. As a silicon oxide film planarizing method in the manufacture of a semiconductor device, chemical mechanical polishing (CMP) using a ceria-based slurry is adopted.

CMP using the ceria-based slurry has a high silicon oxide film polishing rate and achieves a high flatness. However, CMP using the ceria-based slurry poses the following problems.

When CMP using the ceria-based slurry is performed on a semiconductor substrate including a fragile device (for example, an air-gap structure), a fragile layer and silicon oxide film formed on a semiconductor substrate crack, and this makes it impossible to form a circuit in a wide area. Also, many scratches are formed on the silicon oxide film, and they may shortcircuit interconnections. These cracks and scratches are collectively called damages, and it is important to exterminate them.

In addition, CMP generally has a polishing rate difference between a recess and projection of a silicon oxide film, but not only projections but also recesses are removed. To obtain a desired flatness, therefore, a removal amount (polishing allowance) of about 200 nm is necessary from the bottom surface of a recess. In other words, it is necessary to polish about 200 nm from the bottom surface of a recess in order to obtain a desired flatness by CMP. Since CMP is wear destruction, it is desirable to minimize the polishing amount.

Furthermore, it is desirable to reduce the use of a rare-earth element (Ce) contained in the slurry from the viewpoint of the cost.

Unfortunately, a slurry having performance (for example, flatness) equal to that of the ceria-based slurry has not been obtained yet. Thus, demands have arisen for a planarizing method other than CMP using the ceria-based slurry.

### BRIEF DESCRIPTION OF THE DRAWINGS

FIG. 1 is a flowchart showing semiconductor device manufacturing steps according to an embodiment;

FIGS. 2, 3, 4, 5, and 6 are sectional views showing the semiconductor device manufacturing steps according to the embodiment;

FIG. 7 is a view showing the experimental results of flatness when RIE was performed with exposing a silicon oxide film;

FIG. 8 is a view showing the experimental results of flatness when RIE was performed without exposing a silicon oxide film;

FIG. 9 is a perspective view showing the arrangement of a CMP apparatus according to the embodiment;

FIG. 10 is a flowchart showing semiconductor device manufacturing steps according to Comparative Example 1;

FIG. 11 is a sectional view showing a semiconductor device manufacturing step according to Comparative Example 1;

FIG. 12 is a flowchart showing semiconductor device manufacturing steps according to Comparative Example 2;

FIG. 13 is a sectional view showing a semiconductor device manufacturing step according to Comparative Example 2; and

FIG. 14 is a view showing the experimental results of planarization processes according to the embodiment and Comparative Examples 1 and 2.

### DETAILED DESCRIPTION

In general, according to one embodiment, a semiconductor device manufacturing method includes the steps of forming an interlayer dielectric film on a semiconductor substrate, forming a film on the interlayer dielectric film to cover a recess and projection formed on a surface of the interlayer dielectric film, polishing the film by CMP to expose the interlayer dielectric film, and etching the film and the interlayer dielectric film such that etching rates of the film and the interlayer dielectric film are equal.

This embodiment will be explained below with reference to the accompanying drawing. In the drawing, the same reference numbers denote the same parts.

### Embodiment

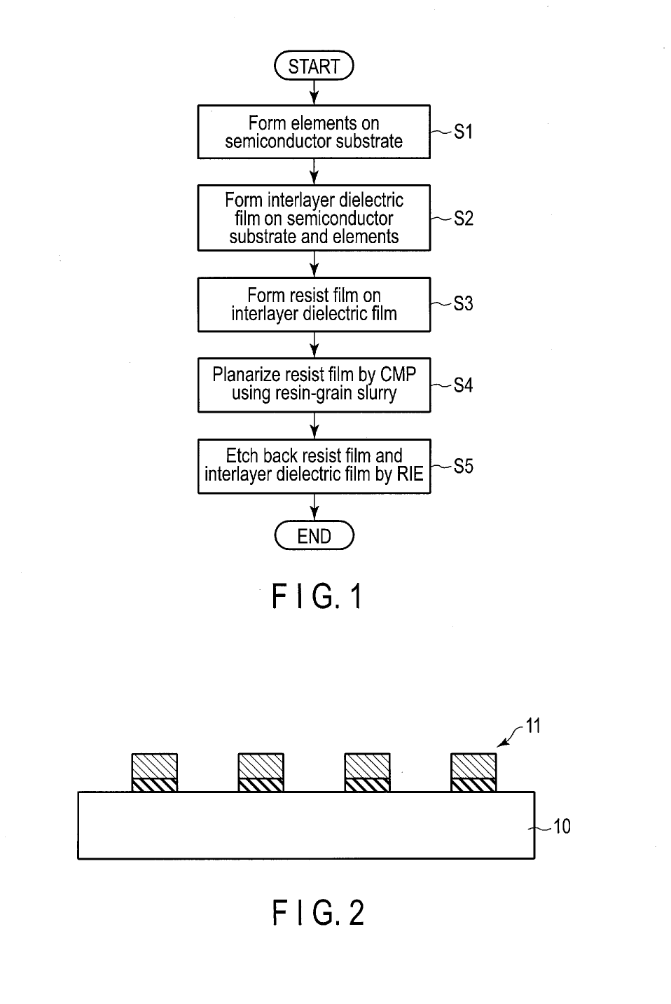

A semiconductor device manufacturing method according to the embodiment will be explained with reference to FIGS. 1, 2, 3, 4, 5, 6, 7, 8, and 9. This embodiment is directed to a method of planarizing an interlayer dielectric film 13 formed on a semiconductor substrate 10 on which elements 11 are arranged. More specifically, an organic film 14 is formed on the interlayer dielectric film 13 having projections and recesses on the surface, and planarized by CMP. After that, the organic film 14 and interlayer dielectric film 13 are etched back by reactive ion etching (RIE). This makes it possible to obtain a desired flatness while reducing damages to the interlayer dielectric film 13. This embodiment will be explained in detail below.

### [Manufacturing Method of Embodiment]

The semiconductor device manufacturing method according to this embodiment will be explained below with reference to FIGS. 1, 2, 3, 4, 5, 6, and 7.

FIG. 1 is a flowchart showing semiconductor device manufacturing steps according to this embodiment. FIGS. 2, 3, 4, 5, and 6 are sectional views showing the semiconductor device manufacturing steps according to this embodiment.

In this embodiment as shown in FIGS. 1 and 2, elements 11 having an air-gap structure (not shown) are first formed on a semiconductor substrate 10 in step S1.

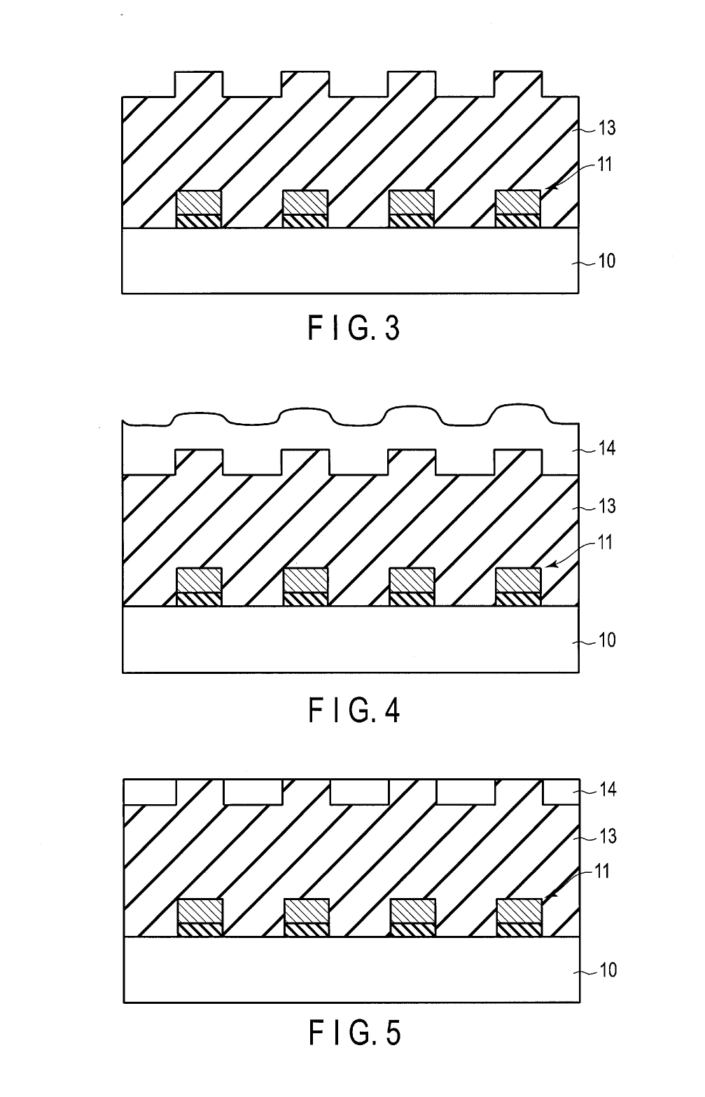

Then, in step S2 as shown in FIGS. 1 and 3, an interlayer dielectric film 13 made of, for example, a silicon oxide film (SiOₓ) is formed on the semiconductor substrate 10 and elements 11. The interlayer dielectric film 13 is so formed as to cover all surfaces of the semiconductor substrate 10 and elements 11.

In this state, projections and recesses are formed on the surface of the interlayer dielectric film 13 because the elements 11 are formed on the semiconductor substrate 10. More specifically, regions above the elements 11 form projections, and regions above portions except for the elements 11 form recesses (trenches). The height of the projection, i.e., the depth of the recess of the interlayer dielectric film 13 is, for example, about 150 nm. Also, the width of the recess and that of the projection are, for example, about 1 μm. In other words, the width/space of the projections (or recesses) is about 1 μm/1 μm.

In this embodiment, the process of planarizing the interlayer dielectric film 13 formed as described above and having the projections and recesses on the surface is performed in steps S3 to S5 below.

First, in step S3 as shown in FIGS. 1 and 4, the interlayer dielectric film 13 having the projections and recesses on the surface is coated with an organic film 14 by the conventional method. Consequently, the surface of the interlayer dielectric film 13 is covered with the organic film 14. More specifically, the recesses of the interlayer dielectric film 13 are filled with the organic film 14. The organic film 14 is also formed on the projections outside the recesses. In this state, projections and recesses are also formed on the surface of the organic film 14 in accordance with the projections and recesses on the surface of the interlayer dielectric film 13. The film thickness of the organic film 14 is, for example, about 300 nm.

The organic film 14 is made of, for example, a resist film mainly containing a novolak-based resin. This resist film mainly containing a novolak-based resin is desirable because the film can be planarized more easily than a resist film mainly containing, for example, cyclohexanone. In addition, the resist film mainly containing a novolak-based resin has high adhesion to the interlayer dielectric film 13 and is not much peeled by CMP, when compared to the resist film mainly containing cyclohexanone. Therefore, the organic film 14 is desirably the resist film mainly containing a novolak-based resin.

After that, the organic film 14 is baked (first baking). The baking temperature is relatively low, i.e., about 100° C. (inclusive) to 170° C. (inclusive). Accordingly, a relatively fragile organic film 14 is formed after the baking. If the baking temperature is lower than 100° C., the adhesion of the organic film 14 may decrease, and this may cause film peeling during CMP in a later step. On the other hand, if the baking temperature exceeds 170° C., the organic film 14 may become harder than resin grains of a slurry, and it may become impossible to remove the organic film 14 by CMP.

Then, in step S4 as shown in FIGS. 1 and 5, the surface of the organic film 14 is polished by CMP using a resin-grain slurry. More specifically, the organic film 14 formed outside the recesses of the interlayer dielectric film 13 is removed, and the organic film 14 formed in the recesses remains. Consequently, the organic film 14 is so polished as to expose the surfaces of the projections of the interlayer dielectric film 13. In this state, the surfaces of the organic films 14 formed in the recesses are leveled with the surfaces of the projections of the interlayer dielectric film 13, i.e., planarization is performed. This step can improve the flatness obtained by CMP in a later step because the interlayer dielectric film 13 is exposed. The basis for this will be described later.

As the resin-grain slurry, it is possible to use, for example, a water dispersion having a pH of 3 and containing 1 wt % of PST (polystyrene) resin grains having a primary grain size of 50 nm, and 0.2 wt % of polyvinylalcohol having a weight-average molecular weight of 1,000.

Note that the resin-grain slurry is not limited to the above-mentioned resin grains and soluble polymer.

The resin grains contain a polymer having a functional group, for example, at least one type of a resin selected from the group consisting of a PST resin, an acrylic resin such as PMMA (polymethylmethacrylate), a urea resin, a melamine resin, a polyacetal resin, a polycarbonate resin, and a composite resin of these resins. In particular, the resin grains are desirably grains containing PMMA, PST, or a styrene-acryl copolymer, because the grains have hardness and elasticity suitable for CMP.

If the average grain size of the resin grains exceeds 5.0 μm or is smaller than 10 nm, the dispersibility of the grains becomes difficult to control, and the slurry readily settles. Accordingly, the average grain size of the resin grains is preferably 10 nm (inclusive) to 5.0 μm (inclusive), and more preferably, 30 nm (inclusive) to 500 nm (inclusive).

Also, the concentration of the resin grains in the resin-grain slurry is preferably 0.01 to 10 wt % (0.01 wt % (inclusive) to 10 wt % (inclusive)), more preferably, 0.1 to 5.0 wt %, and most preferably, 0.3 to 3.0 wt %. If the concentration of the resin grains is less than 0.01 wt %, the polishing rate may extremely decrease. On the other hand, if the concentration of the resin grains exceeds 10 wt %, dishing may become worse.

The soluble polymer is not limited. Examples are soluble celluloses such as methylcellulose, methylhydroxyethylcellulose, methylhydroxypropylcellulose, hydroxyethylcellulose, hydroxypropylcellulose, carboxymethylcellulose, carboxyethylcellulose, and carboxymethylhydroxyethylcellulose; soluble polysaccharides such as chitosan, hyaluronic acid, chondroitin, chondroitin sulfate, chondroitin polysulfate, dermatan sulfate, heparin, keratan sulfate, keratan polysulfate, starch, dextrin, polydextrose, xanthan gum, and guar gum; polyvinylalcohol, polyethyleneglycol, polyethylene imine, polyvinylpyrrolidone, polyacrylic acid and its salt, polyacrylamide, and polyethyleneoxide. It is particularly desirable to use polyvinylalcohol or polyvinylpyrrolidone by which a high flatness can be obtained. These soluble polymers can be used singly or in the form of a mixture of two or more types thereof.

The molecular weight of the soluble polymer is preferably 500 to 1,000,000, more preferably, 1,000 to 500,000, and most preferably, 5,000 to 300,000. If the molecular weight of the soluble polymer is less than 500, the interaction with the organic film 14 (an organic film) becomes weak. Since this weakens the adsorbing effect and protecting effect, dishing may become impossible to suppress. On the other hand, if the molecular weight of the soluble polymer exceeds 1,000,000, the adsorbing effect becomes too large, and the polishing rate decreases. In addition, the viscosity becomes too high, and this sometimes makes the supply of the slurry difficult.

In the resin-grain slurry, the concentration of the soluble polymer is 0.001 to 10 wt %, preferably, 0.01 to 1 wt %, and more preferably, 0.05 to 0.5 wt %. If the concentration of the soluble polymer is less than 0.001 wt %, the slurry does not function as a lubricant between the polishing pad and a wafer. This sometimes causes film peeling and makes it impossible to suppress dishing. On the other hand, if the concentration of the soluble polymer exceeds 10 wt %, excessive adsorption to the organic film 14 (an organic film) sometimes extremely decreases the polishing rate.

Note that a normally used amount of an additive such as an oxidizer, organic acid, or surfactant may be blended in the resin-grain slurry as needed.

Also, the pH of the resin-grain slurry may be defined from 2 (inclusive) to 8 (inclusive). If the pH is less than 2, the dissociation of the functional group such as COOH becomes difficult, and the dispersibility sometimes worsens. On the other hand, if the pH exceeds 8, chemical damages to the organic film 14 (an organic film) become large, and dishing sometimes increases.

For example, the resin-grain slurry can be controlled to have a pH falling within the above-described range by properly blending a pH control agent. As the pH control agent, it is possible to use, for example, an inorganic acid (for example, nitric acid, phosphoric acid, hydrochloric acid, or sulfuric acid), or an organic acid (for example, citric acid).

After that, the organic film 14 is baked (second baking). The baking temperature is relatively high, i.e., 200° C. (inclusive) to 400° C. (inclusive), and higher than the first baking temperature. Therefore, a relatively strong organic film 14 is formed after the baking. If the baking temperature is lower than 200° C., thermosetting may become insufficient. On the other hand, if the baking temperature exceeds 400° C., a polymer forming the organic film 14 may decompose. Since this second baking is performed, it is possible to adjust the etching rate of the organic film 14 during RIE in a later step. More specifically, since the second baking is performed at a relatively high temperature, it is possible to strengthen the organic film 14 and decrease the etching rate of the organic film 14.

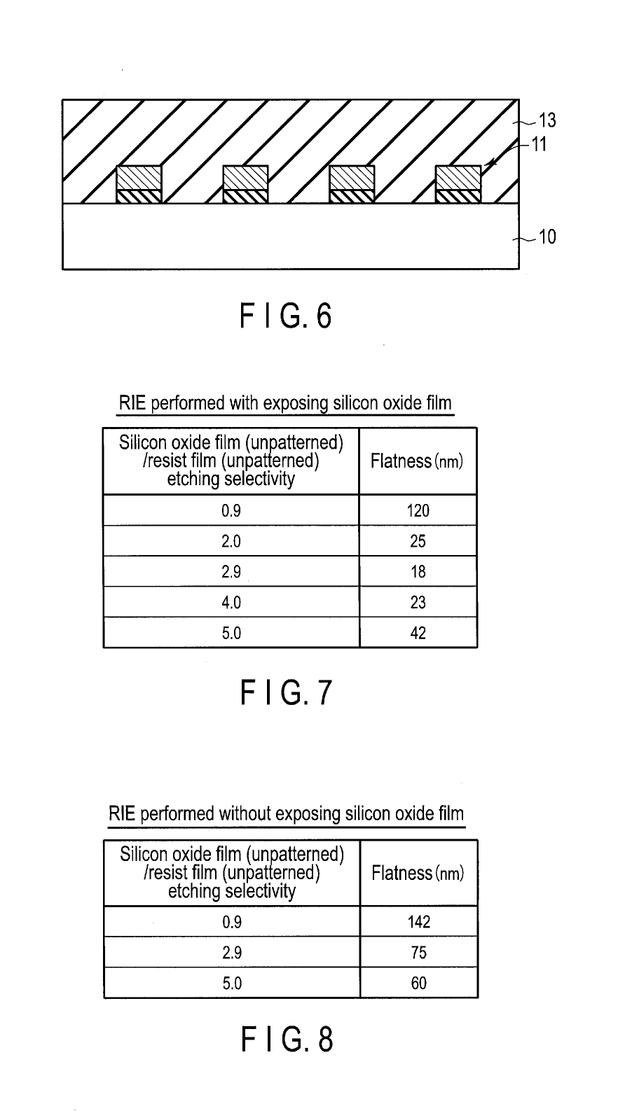

Subsequently, in step S5 as shown in FIGS. 1 and 6, the interlayer dielectric film 13 and organic film 14 are etched back by RIE. As etching gases for RIE, CF₄ and CH₂F₂ or CF₄ and O₂ are used. In this step, the amounts (mixing ratio) of CF₄ and CH₂F₂ or CF₄ and O₂ are adjusted such that the etching rate ratio (silicon oxide film (patterned)/organic film (patterned), to be referred to as a patterned film etching rate ratio hereinafter) of the patterned interlayer dielectric film 13 (a silicon oxide film) and the patterned organic film 14 is 1.0 (such that the etching rates are equal). This makes it possible to improve the flatness by RIE.

More specifically, to set the patterned film etching rate ratio at 1.0, the etching gas amounts need only be adjusted so that when both the interlayer dielectric film 13 and organic film 14 are unpatterned films, the etching rate ratio (silicon oxide film (unpatterned)/organic film (unpatterned), to be referred to as an unpatterned film etching rate ratio hereinafter) is about 2.0.

This is so probably because when simultaneously etching a patterned silicon oxide film and the patterned organic film 14 by RIE, the etching reaction of the organic film 14 advances faster than that of the silicon oxide film. In other words, the etching rate of the organic film 14 is higher when it is etched as an unpatterned film than when it is etched as a patterned film simultaneously with a silicon oxide film. The reason for this is as follows. Etching of the organic film 14 requires O₂. This O₂ is supplied as an etching gas for RIE. However, when simultaneously etching a patterned silicon oxide film and the patterned organic film 14, the etched silicon oxide film also produces O₂. This O₂ produced by the silicon oxide film and O₂ supplied as an etching gas advance the etching reaction of the organic film 14. That is, the etching rate of the organic film 14 increases under the influence of O₂ produced by the silicon oxide film.

Note that the unpatterned film etching rate ratio of the silicon oxide film and organic film 14 for improving the flatness is not limited to 2.0. When the high-temperature second baking is not performed before RIE, the unpatterned film etching rate ratio is about 2.0 (inclusive) to 4.0 (inclusive), and desirably, about 2.9. The basis for this will be described later.

Note that the unpatterned film etching rate ratio for setting the patterned film etching rate ratio at 1.0 when the high-temperature second baking is performed before RIE is lower (2.0) than that (2.9) when no second baking is performed. This is so because the organic film 14 strengthened by the second baking is hardly influenced by O₂ supplied from the silicon oxide film. That is, when the organic film 14 is strengthened by the second baking, the etching rate difference between the unpatterned organic film 14 and patterned organic film 14 decreases. When the ratio of the unpatterned film etching rate ratio to the patterned film etching rate ratio is thus low, the dependence of the etching rate on a pattern decreases, so it is possible to uniformly planarize any patterns. Therefore, the high-temperature second baking is desirably performed before RIE in order to improve the flatness.

The etching rates of the silicon oxide film and organic film 14 are, for example, about 200 nm/min.

Consequently, the organic film 14 on the projections of the interlayer dielectric film 13 and in the recesses of the interlayer dielectric film 13 is completely removed. In addition, the bottom surface of each recess of the interlayer dielectric film 13 is etched back by about 100 nm. In this step, the removal amount (removal film thickness) from the bottom surface of each recess of the interlayer dielectric film 13 is set at preferably 100 nm or less, and more preferably, 50 nm or less. That is, it is desirable to reduce the removal amount from the bottom surface of each recess of the interlayer dielectric film 13 as much as possible. Also, the removal amount of the interlayer dielectric film 13 and organic film 14 by RIE is desirably smaller than that of the organic film 14 by CMP.

The damage and flatness resulting from the planarizing method of this embodiment will be described later.

The process of planarizing the interlayer dielectric film 13 according to this embodiment is performed as described above.

The reason why the unpatterned film etching rate ratio is 2.0 (inclusive) to 4.0 (inclusive) in RIE and the reason why RIE is performed by exposing the interlayer dielectric film 13 (a silicon oxide film) according to this embodiment will be explained below.

FIG. 7 is a view showing the experimental results of the flatness when RIE was performed with exposing the silicon oxide film.

As shown in FIG. 7, when RIE was performed by exposing the silicon oxide film, the flatness (the difference between the projections and recesses of the surface) was larger than 25 nm when the unpatterned film etching rate ratio was lower than 2.0. When the unpatterned film etching rate ratio increased to 2.0 (inclusive) to 4.0 (inclusive), it was possible to decrease the flatness to 25 nm or less. When the unpatterned film etching rate ratio further increased and exceeded 4.0, the flatness was larger than 25 nm. This flatness is desirably 25 nm or less. In this embodiment, therefore, the unpatterned film etching rate ratio is desirably 2.0 (inclusive) to 4.0 (inclusive). As described previously, this unpatterned film etching rate ratio can be controlled by adjusting the second baking temperature after CMP and the etching gas mixing ratio.

On the other hand, FIG. 8 is a view showing the experimental results of the flatness when RIE was performed without exposing the silicon oxide film.

As shown in FIG. 8, when RIE was performed without exposing the silicon oxide film, the flatness was inferior to that when RIE was performed by exposing the silicon oxide film. More specifically, when compared to the case (FIG. 7) in which RIE was performed by exposing the silicon oxide film, the flatness deteriorated at all unpatterned film etching rate ratios (0.9, 2.9, and 5.0).

This is so because a portion where etching reached the reference surface (the surface to which the interlayer dielectric film 13 and organic film 14 were exposed) varied under the influences of the residual organic film after CMP and the in-plane uniformity of RIE. That is, the exposure timing of the interlayer dielectric film 13 varied from one portion to another, and this made the O₂ supply amount from the silicon oxide film indeterminate. Consequently, the influence of O₂ from the silicon oxide film on the etching rate of the organic film 14 changed from one place to another.

In this embodiment, therefore, RIE of the organic film 14 and interlayer dielectric film 13 is desirably performed after the interlayer dielectric film 13 is exposed by CMP of the organic film 14.

### [CMP Apparatus]

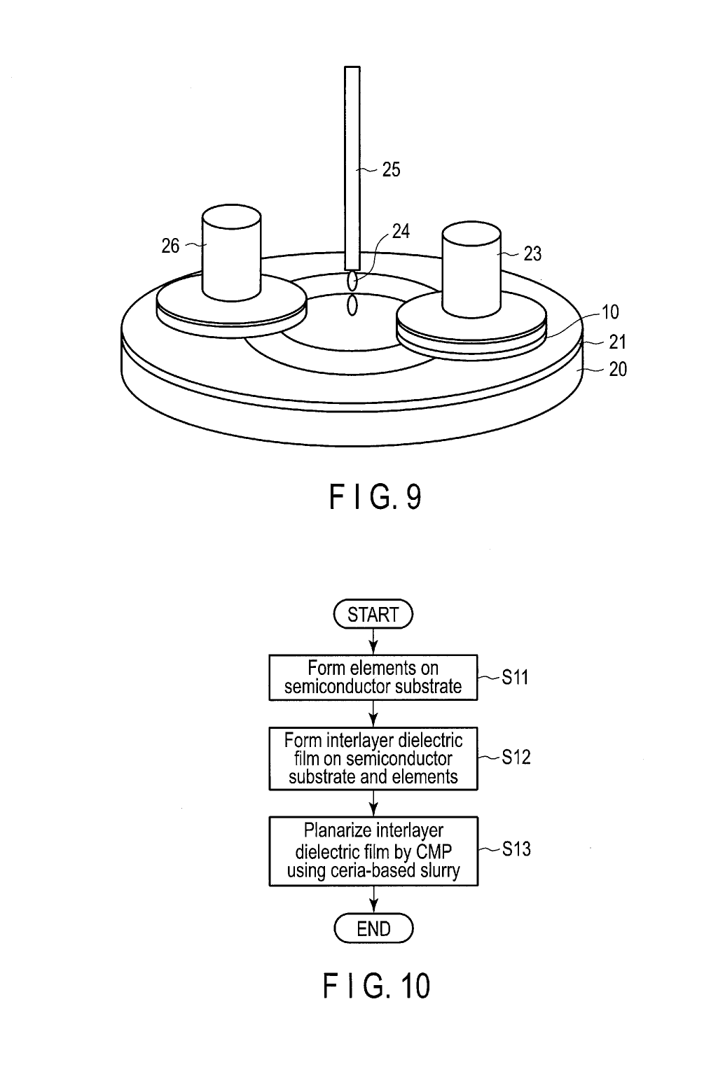

A CMP apparatus according to this embodiment will be explained below with reference to FIG. 9.

FIG. 9 is a perspective view showing the arrangement of the CMP apparatus according to this embodiment.

As shown in FIG. 9, the CMP apparatus according to this embodiment includes a turntable 20, polishing pad 21, top ring 23, slurry supply nozzle 25, and dresser 26.

The top ring 23 holding the semiconductor substrate 10 is brought into contact with the polishing pad 21 adhered on the turntable 20. A film to be processed (for example, the organic film 14 shown in FIG. 4) is formed on the semiconductor substrate 10. The turntable 20 can rotate at 1 to 200 rpm, and the top ring 23 can rotate at 1 to 200 rpm. The turntable 20 and top ring 23 rotate in the same direction, for example, rotate counterclockwise. Also, the turntable 20 and top ring 23 rotate in a predetermined direction during CMP. The polishing load of these members is normally about 50 to 500 hPa.

The slurry supply nozzle 25 is positioned above the polishing pad 21. The slurry supply nozzle 25 can supply a predetermined liquid chemical as a slurry 24 at a flow rate of 50 to 500 cc/min. The slurry supply nozzle 25 is positioned near, for example, the center of the turntable 20, but the position is not limited to this, and the slurry supply nozzle 25 may also be positioned such that the slurry 24 is supplied to the entire surface of the polishing pad 21.

Note that FIG. 9 also shows the dresser 26 for conditioning the surface of the polishing pad 21. The dresser 26 is normally rotated at 1 to 200 rpm, and brought into contact with the polishing pad 21 with a load of 50 to 500 hPa.

A cooling nozzle for spraying compressed air or gaseous nitrogen toward the polishing pad 21 may also be positioned above the polishing pad 21. The cooling nozzle is positioned on the radius of the polishing pad 21 around the slurry supply nozzle 25 (the rotating shaft of the turntable 20), and can spray compressed air or the like against the entire surface of the polishing pad 21 because the polishing pad 21 is rotating.

### [Manufacturing Method of Comparative Example 1]

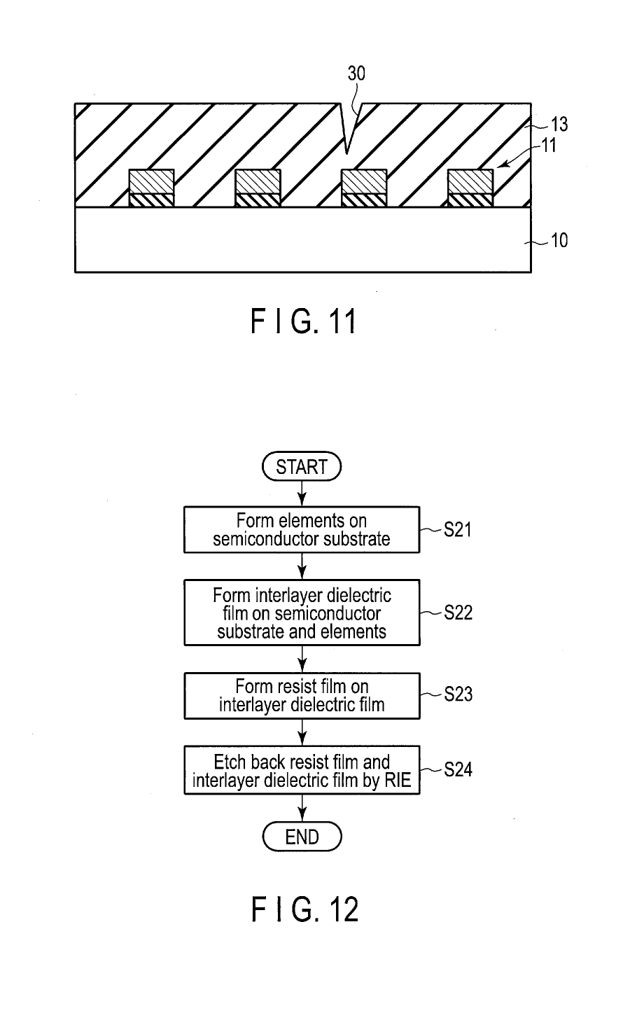

A semiconductor device manufacturing method according to Comparative Example 1 will be explained below with reference to FIGS. 10 and 11. Comparative Example 1 differs from the embodiment in that no organic film 14 is formed, and the interlayer dielectric film 13 is planarized by CMP using a ceria-based slurry. Note that in Comparative Example 1, an explanation of the same features as those of the embodiment will be omitted.

FIG. 10 is a flowchart showing semiconductor device manufacturing steps according to Comparative Example 1. FIG. 11 is a sectional view showing a semiconductor device manufacturing step according to Comparative Example 1.

In Comparative Example 1, the same steps as shown in FIGS. 2 and 3 of the embodiment (steps S1 and S2 shown in FIG. 1) are first performed. More specifically, in step S11 as shown in FIG. 10, elements (transistors) as semiconductor devices are formed on a semiconductor substrate 10. After that, in step S12, an interlayer dielectric film 13 made of, for example, a silicon oxide film (SiOₓ) is formed on the semiconductor substrate 10 and elements. Since the elements are formed on the semiconductor substrate 10, projections and recesses are formed on the surface of the interlayer dielectric film 13.

In Comparative Example 1, a process of planarizing the interlayer dielectric film 13 formed as described above and having the projections and recesses on the surface is performed in step S13 below.

In step S13 as shown in FIGS. 10 and 11, the surface of the interlayer dielectric film 13 is planarized by CMP using a ceria-based slurry. To planarize the interlayer dielectric film 13 by this CMP, the removal amount from the bottom surface of each recess of the interlayer dielectric film 13 must be 200 nm or more. Also, as shown in FIG. 11, damage (a scratch or crack) 30 occurs on the interlayer dielectric film 13 when CMP using a ceria-based slurry is performed on the interlayer dielectric film 13. The damage and flatness resulting from the planarizing method of Comparative Example 1 will be described later.

Thus, the process of planarizing the interlayer dielectric film 13 according to Comparative Example 1 is performed.

### [Manufacturing Method of Comparative Example 2]

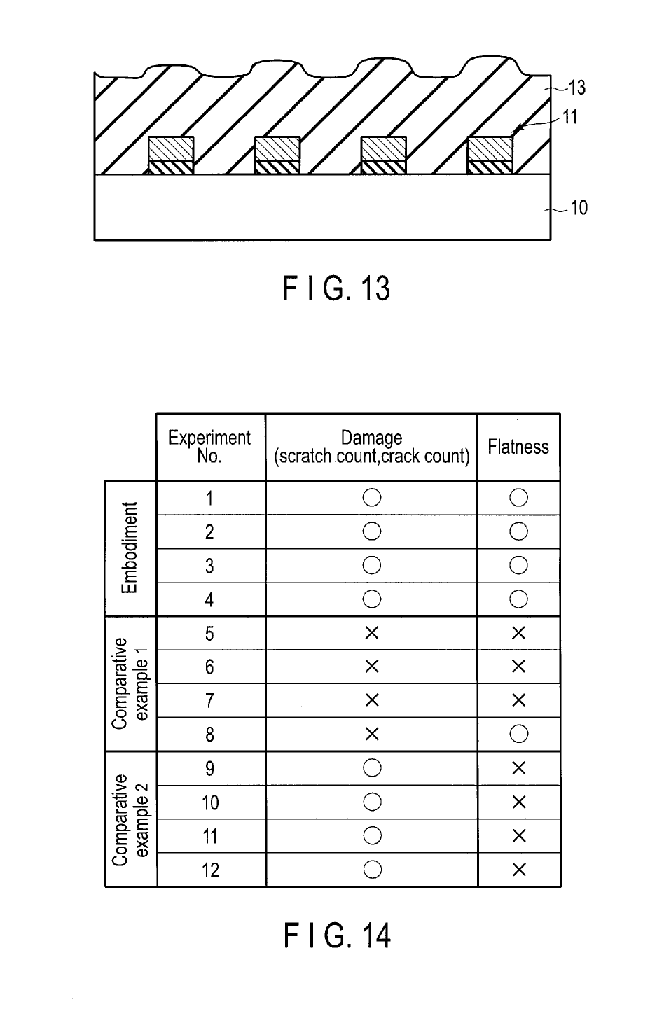

A semiconductor device manufacturing method according to Comparative Example 2 will be explained below with reference to FIGS. 12 and 13. Comparative Example 2 differs from the embodiment in that no CMP is performed on the organic film 14 after it is formed, and the interlayer dielectric film 13 and organic film 14 are planarized by RIE. Note that in Comparative Example 2, an explanation of the same features as those of the embodiment will be omitted.

FIG. 12 is a flowchart showing semiconductor device manufacturing steps according to Comparative Example 2. FIG. 13 is a sectional view showing a semiconductor device manufacturing step according to Comparative Example 2.

In Comparative Example 2, the same steps as shown in FIGS. 2 and 3 of the embodiment (steps S1 and S2 shown in FIG. 1) are first performed. More specifically, in step S21 as shown in FIG. 12, elements (transistors) as semiconductor devices are formed on a semiconductor substrate 10. Then, in step S22, an interlayer dielectric film 13 made of, for example, a silicon oxide film (SiOₓ) is formed on the semiconductor substrate 10 and elements. Since the elements are formed on the semiconductor substrate 10, projections and recesses are formed on the surface of the interlayer dielectric film 13.

In Comparative Example 2, a process of planarizing the interlayer dielectric film 13 formed as described above and having the projections and recesses on the surface is performed in steps S23 and S24 below.

First, the same step as shown in FIG. 4 of the embodiment (step S3 shown in FIG. 1) is performed. More specifically, in step S23 as shown in FIG. 12, the interlayer dielectric film 13 having the projections and recesses on the surface is coated with an organic film 14 by the conventional method. In this step, projections and recesses are also formed on the surface of the organic film 14 in accordance with the projections and recesses on the surface of the interlayer dielectric film 13.

After that, the organic film 14 is baked. The baking temperature is a relative low temperature, i.e., about 100° C. (inclusive) to 170° C. (inclusive).

Then, in step S24 as shown in FIGS. 12 and 13, the interlayer dielectric film 13 and organic film 14 are etched back by RIE. As etching gases for RIE, CF₄ and CH₂F₂ or CF₄ and O₂ are used. As shown in FIG. 13, the projections and recesses remain on the surface of the interlayer dielectric film 13 when the organic film 14 and interlayer dielectric film 13 are etched back by RIE without performing CMP after the organic film 14 is formed. That is, no desired flatness can be obtained on the surface of the interlayer dielectric film 13. The damage and flatness resulting from the planarizing method of Comparative Example 2 will be described later.

Thus, the process of planarizing the interlayer dielectric film 13 according to Comparative Example 2 is performed.

### [Planarization Experiments]

The experimental results of the damage and flatness resulting from the planarization of the interlayer dielectric film 13 according to the embodiment and Comparative Examples 1 and 2 will be explained below with reference to FIG. 14.

Experiments were conducted by performing the planarization processes of the embodiment and Comparative Examples 1 and 2 on the interlayer dielectric film 13 having projections and recesses on the surface, and measuring the resulting damage and flatness. The measurements were performed by changing the removal amount from the bottom surface of each recess of the interlayer dielectric film 13 in the planarization processes of the embodiment and Comparative Examples 1 and 2.

More specifically, in the planarization process of the embodiment (the method of forming the organic film 14, polishing the organic film 14 by CMP using a resin-grain slurry, and etching back the organic film 14 and interlayer dielectric film 13 by RIE), the removal amount from the bottom surface of each recess of the interlayer dielectric film 13 was changed to 50 nm (Experiment 1), 100 nm (Experiment 2), 150 nm (Experiment 3), and 200 nm (Experiment 4).

Also, in the planarizing process of Comparative Example 1 (the method of forming no organic film 14, and polishing the interlayer dielectric film 13 by CMP using a ceria-based slurry), the removal amount from the bottom surface of each recess of the interlayer dielectric film 13 was changed to 50 nm (Experiment 5), 100 nm (Experiment 6), 150 nm (Experiment 7), and 200 nm (Experiment 8).

Furthermore, in the planarizing process of Comparative Example 2 (the method of forming the organic film 14, and etching back the organic film 14 and interlayer dielectric film 13 by RIE), the removal amount from the bottom surface of each recess of the interlayer dielectric film 13 was changed to 50 nm (Experiment 9), 100 nm (Experiment 10), 150 nm (Experiment 11), and 200 nm (Experiment 12).

In each of Experiments 1 to 12 described above, the damage (scratch or crack) and flatness of the interlayer dielectric film 13 were evaluated.

FIG. 14 is a view showing the experimental results of the planarizing processes of the embodiment and Comparative Examples 1 and 2. The damage and flatness of the interlayer dielectric film 13 were evaluated based on the following criteria. The damage was measured by KLA2815 (KLA-Tencor) SEM Reviw. The flatness was measured by an atomic force microscope (AFM). ◯ indicates an allowable range for both the damage and flatness.
Damage . . . ◯: zero, ×: one or more (per wafer)
Flatness . . . ◯: 25 nm or less, ×: more than 25nm (the difference between the projection and recess on the surface)

The basis of the evaluation of these damage and flatness was the possibility of a shortcircuit between interconnections.

As shown in FIG. 14, in the process of planarizing the interlayer dielectric film 13 according to the embodiment, both the damage and flatness fell within the allowable ranges in Experiments 1 to 4. In the embodiment, no damage occurred on the interlayer dielectric film 13 probably because no CMP was directly performed on the interlayer dielectric film 13. Also, it was presumably possible to obtain a desired flatness by planarizing the organic film 14 and interlayer dielectric film 13 by polishing the organic film 14 having a film thickness of about 200 nm by CMP, and then etching back these films by RIE.

As described above, the removal amount of the interlayer dielectric film 13 during planarization is desirably as small as possible. In the embodiment as indicated by Experiment 1, the removal amount from the bottom surface of each recess of the interlayer dielectric film 13 can be reduced to 50 nm (or less) while increasing the flatness without causing damage.

On the other hand, in the process of planarizing the interlayer dielectric film 13 according to Comparative Example 1, the damage did not fall within the allowable range in all Experiments 5 to 8. This is so because damages readily occur when performing CMP by using a ceria-based slurry. In Experiment 5 in which the removal amount was small, the damage improved but fell outside the allowable range. Also, the flatness fell outside the allowable range in Experiments 5 to 7. In Experiment 8 in which the removal amount was large, the flatness improved and fell within the allowable range. This is so because a polishing allowance of about 200 nm is necessary to obtain a desired flatness in CMP using a ceria-based slurry.

In the process of planarizing the interlayer dielectric film 13 according to Comparative Example 2, the damage fell within the allowable range in all Experiments 9 to 12. That is, no damage occurred because no CMP was performed in Comparative Example 2. On the other hand, the flatness fell outside the allowable range in all Experiments 9 to 12. That is, the planarizing process of Comparative Example 2 was insufficient because no CMP was performed.

### [Effects]

In the above-mentioned embodiment, in the process of planarizing the interlayer dielectric film 13 (a silicon oxide film) having projections and recesses on the surface, the organic film 14 is formed on the interlayer dielectric film 13 so as to cover the projections and recesses. After that, CMP using a resin-grain slurry is performed on the organic film 14, thereby planarizing the surfaces of the organic film 14 and interlayer dielectric film 13. Then, the organic film 14 and interlayer dielectric film 13 are etched back by RIE. This can reduce damages inflicted on the interlayer dielectric film 13 in the planarizing process. Also, a desired flatness can be obtained even when the removal amount from the bottom surface of each recess of the interlayer dielectric film 13 is 100 nm (more preferably, 50 nm) or less. That is, it is possible to provide, for a silicon oxide film, a planarizing method having performance higher than that of CMP using a ceria-based slurry.

Note that the organic film 14 is formed for the planarization of the interlayer dielectric film 13 in the embodiment, but the present embodiment is not limited to this. Instead of the organic film 14, it is also possible to use a film that can be polished by CMP using a resin-grain slurry, and can be etched by RIE at the same etching rate ratio as that of the interlayer dielectric film 13. An example of the film is a TiN film. When using the TiN film, it is possible to use, as a resin-grain slurry of CMP, a water dispersion containing various resin grains, 2.0 wt % of APS (ammonium persulfate), 0.3 wt % of quinolinic acid, and 0.5 wt % of glycine, and having a pH of 9 controlled by using potassium hydroxide. Also, when etching the patterned TiN film and interlayer dielectric film 13 at the same etching rate by RIE, the etching gas amount is adjusted such that the unpatterned film etching rate ratio is about 2.0.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device manufacturing method comprising:
forming an interlayer dielectric film on a semiconductor substrate;
forming a film on the interlayer dielectric film to cover a recess and projection formed on a surface of the interlayer dielectric film;
polishing the film by CMP to expose the interlayer dielectric film; and
etching the film and the interlayer dielectric film such that etching rates of the film and the interlayer dielectric film are equal.

2. The method of claim 1, wherein the etching the film and the interlayer dielectric film is performed such that a removal amount of the interlayer dielectric film from a bottom surface of the recess is not more than 100 nm.

3. The method of claim 1, further comprising:
performing first baking on the film before the polishing the film; and
performing second baking on the film at a temperature higher than that of the first baking, before the etching back the film and the interlayer dielectric film.

4. The method of claim 3, wherein the first baking is performed at a temperature of 100° C.(inclusive) to 170° C. (inclusive), and the second baking is performed at a temperature of 200° C. (inclusive) to 400° C. (inclusive).

5. The method of claim 1, wherein the CMP is performed using a resin-grain slurry.

6. The method of claim 5, wherein the resin-grain slurry contains resin grains and a soluble polymer.

7. The method of claim 6, wherein the resin grains contain at least one of a resin selected from the group consisting of a PST resin, an acrylic resin, a urea resin, a melamine resin, a polyacetal resin, and a polycarbonate resin.

8. The method of claim 6, wherein a grain size of the resin grains is 30 nm (inclusive) to 500 nm (inclusive).

9. The method of claim 6, wherein a concentration of the resin grains is 0.3 wt % (inclusive) to 3.0 wt % (inclusive).

10. The method of claim 6, wherein the soluble polymer contains a material selected from the group consisting of methylcellulose, methylhydroxyethylcellulose, methylhydroxypropylcellulose, hydroxyethylcellulose, hydroxypropylcellulose, carboxymethylcellulose, carboxyethylcellulose, carboxymethylhydroxyethylcellulose, chitosan, hyaluronic acid, chondroitin, chondroitin sulfate, chondroitin polysulfate, dermatan sulfate, heparin, keratan sulfate, keratan polysulfate, starch, dextrin, polydextrose, xanthan gum, guar gum, olyvinylalcohol, polyethyleneglycol, polyethyleneimine, polyvinylpyrrolidone, polyacrylic acid and salt thereof, polyacrylamide, and polyethyleneoxide.

11. The method of claim 6, wherein a molecular weight of the soluble polymer is 5,000 (inclusive) to 300,000 (inclusive).

12. The method of claim 6, wherein a concentration of the soluble polymer is 0.05 wt % (inclusive) to 0.5 wt % (inclusive).

13. The method of claim 5, wherein a pH of the resin-grain slurry is 2 (inclusive) to 8 (inclusive).

14. The method of claim 1, wherein the etching the film and the interlayer dielectric film is performed by RIE.

15. The method of claim 14, wherein CF₄ and CH₂F₂ or CF₄ and O₂ are used as etching gases for RIE.

16. The method of claim 1, wherein an amount by which the film is polished in the polishing the film is smaller than an amount by which the film and the interlayer dielectric film are etched in the etching the film and the interlayer dielectric film.

17. The method of claim 1, wherein the film comprises a resist film mainly containing a novolak resin.

18. The method of claim 1, wherein the film comprises a TiN film.

19. The method of claim 1, wherein the interlayer dielectric film comprises a silicon oxide film.

20. The method of claim 1, further comprising forming an element having an air-gap structure on the semiconductor substrate, before the forming the interlayer dielectric film.
